(19) United States
(12) Patent Application Publication
(10) Pub. No.: US 2025/0388507 A1
(43) Pub. Date: Dec. 25, 2025

(54) OLED GLASS WITH IMPROVED OPTICAL PERFORMANCE

(71) Applicants: CNBM RESEARCH INSTITUTE FOR ADVANCED GLASS MATERIALS GROUP CO., LTD., Bengbu (CN); China National Building Material Group Co., Ltd., Beijing (CN)

(72) Inventors: Shou PENG, Bengbu (CN); Chong ZHANG, Bengbu (CN); Na HAN, Bengbu (CN); Xin CAO, Bengbu (CN); Wentao HU, Bengbu (CN); Changqing LI, Bengbu (CN); Yong YANG, Bengbu (CN); Gang ZHOU, Bengbu (CN); Peng WANG, Bengbu (CN); Xiaoyu ZHANG, Bengbu (CN); Zhenkun KE, Bengbu (CN); Jiedong CUI, Bengbu (CN); Chuanli SHAN, Bengbu (CN); Can LIU, Bengbu (CN); Lifen SHI, Bengbu (CN); Zhaojin ZHONG, Bengbu (CN); Qiang GAO, Bengbu (CN); Pingping WANG, Bengbu (CN); Fengyang ZHAO, Bengbu (CN); Weiwei WANG, Bengbu (CN); Jia NI, Bengbu (CN); Jinwei LI, Bengbu (CN)

(73) Assignees: CNBM RESEARCH INSTITUTE FOR ADVANCED GLASS MATERIALS GROUP CO., LTD., Bengbu (CN); China National Building Material Group Co., Ltd., Beijing (CN)

(21) Appl. No.: 18/880,259

(22) PCT Filed: Aug. 11, 2023
(86) PCT No.: PCT/CN2023/112608

§ 371 Date: Dec. 30, 2024

(30) Foreign Application Priority Data
Dec. 28, 2022 (CN) 202211714747.4

(51) Int. Cl. C03C 3/118; H10K 77/10

(52) U.S. Cl. CPC C03C 3/118; H10K 77/10

(57) ABSTRACT

An OLED glass with improved optical performance relates to the field of glass production and manufacturing, and is manufactured from the following raw materials in percentage by weight: 57-62% of SiO₂, 20-24% of Al₂O₃, 0.5-2% of B₂O₃, 2-5% of BaF₂, 8-11% of SrO, 0.5-1.5% of BeF₂, 0.2-0.5% of SnO₂, 0.3-1.0% of La₂O₃, 0.2-1.0% of P₂O₅, 0.2-0.8% of AlF₃, and 0.1-0.3% of AgNO₃. Silicon dioxide and aluminum oxide are sieved and stirred uniformly, mixed uniformly with the remaining raw materials, melted, thinned in a tin bath and formed, annealed, and cut, to obtain a product. The glass not only meets the performance of optical glass, but also has excellent mechanical performance and thermal performance, which has an improved application prospect in OLED glass and display industries.

### FIELD OF THE INVENTION

The present invention relates to the field of glass production and manufacturing, and specifically, to an OLED glass with improved optical performance.

### BACKGROUND OF THE INVENTION

With the rapid development of electronic information display industries, display products develop from cathode ray tubes (CRTs) to thin and light liquid crystal displays (LCDs) and then to organic light-emitting displays (OLEDs), which belongs to the third-generation display technology. OLEDs have the advantages of self-illumination, wide viewing angles, low power consumption, high contrast, and fast response, and are available to flexible display which are now widely used in TVs, panels, and other fields. Glass substrates are the key basic material of OLED displays, and are mainly used in TFT manufacturing and substrates of CF devices, in which relevant circuit fabrication and processing are carried out on the glass surface. OLED display products have a laminated structure, with organic light-emitting materials placed between functional layers. In addition, with the development of digital and highly refined display devices, optical components used in the devices are highly required in materials. Therefore, glass substrates, which are indispensable, must meet some special requirements, including high transmittance, low photoelastic coefficient, high Abbe number, high strain point, high hardness, high modulus of elasticity, and the like. Therefore, glass substrates are irreplaceable inorganic non-metallic materials for the OLEDs and play an important role in the display industry.

Currently, the performance, such as a strain point, hardness, and transmittance, of glass substrates for the OLED display can basically meet the requirements. However, there are limited studies on the optical performance, such as photoelastic coefficient, Abbe number, and modulus of elasticity, for OLED glass. Poor optical performance and poor internal homogeneity of the glass lead to anisotropy, resulting in non-uniform performance and poor repeatability of the glass. The stressed glass appears anisotropic, leading to birefringence. For the photoelastic coefficient of the glass, if the internal structure of the glass is inhomogeneous or the residual stress is large, the photoelastic coefficient will be large, which further affects the performance of the glass. The glass with a small photoelastic coefficient indicates improved anisotropy, which is more suitable for optical devices. In addition, various defects in the OLED glass have a great impact on optical performance and mechanical performance of the glass. For raw materials of the glass, as silicon and aluminum raw materials are mainly used for the OLED glass, defects such as knots and stones are caused by inhomogeneity and non-uniform particle sizes of the silicon and aluminum raw materials, which leads to a great reduction in various performance of the glass. Moreover, there are also limited studies on the defects caused by the raw materials of such glass, resulting in poor optical performance and low product yields of such glass. To improve the image display quality, the display glass is required to have higher quality and fewer defects.

Furthermore, some researchers have added environmentally unfriendly raw materials such as Pb and V to glass for optical display devices. Such devices cannot be used in large quantities, although they have superior performance. In addition, some researchers have manufactured optical glass with at least two or three types of rare earth raw materials used in raw materials of the glass, making the glass expensive to popularize.

### SUMMARY OF THE INVENTION

An objective of the present invention is to resolve the problems of high photoelastic coefficient, low Abbe number, low modulus of elasticity, non-uniform internal performance of glass, and high defect rate and low product yield caused by silicon and aluminum raw materials of the existing glass for OLED display, and to provide an OLED glass with improved optical performance. The glass of the present invention has a low defect rate, a low melting point, high transmittance, a small photoelastic coefficient, a high Abbe number, a high strain point, high modulus of elasticity, high Vickers hardness, and a high degree of uniformity in the physical and chemical performance. Therefore, the difficulty in the float glass process is effectively reduced, the optical performance of the glass is greatly improved while ensuring high mechanical performance, and the product yield is increased. In addition, the glass with this chemical composition has a simple manufacturing process, which is convenient to implement.

The objective of the present invention may be achieved through the following technical solutions:

An OLED glass with improved optical performance is made from the following raw materials in percentage by weight: 57-62% of SiO₂, 20-24% of Al₂O₃, 0.5-2% of B₂O₃, 2-5% of BaF₂, 8-11% of SrO, 0.5-1.5% of BeF₂, 0.2-0.5% of SnO₂, 0.3-1.0% of La₂O₃, 0.2-1.0% of P₂O₅, 0.2-0.8% of AlF₃, and 0.1-0.3% of AgNO₃.

Further, the OLED glass is made from the following raw materials in percentage by weight: 57-62% of SiO₂, 20-24% of Al₂O₃, 0.5-2% of B₂O₃, 2-4% of BaF₂, 8-10% of SrO, 0.6-1.2% of BeF₂, 0.2-0.5% of SnO₂, 0.3-0.8% of La₂O₃, 0.2-0.8% of P₂O₅, 0.2-0.7% of AlF₃, and 0.1-0.25% of AgNO₃.

Further, the OLED glass is made from the following raw materials in percentage by weight: 57-62% of SiO₂, 20-24% of Al₂O₃, 0.5-2% of B₂O₃, 2-4% of BaF₂, 8-10% of SrO, 0.6-1.2% of BeF₂, 0.2-0.5% of SnO₂, 0.3-0.8% of La₂O₃, 0.2-0.6% of P₂O₅, 0.3-0.7% of AlF₃, and 0.1-0.25% of AgNO₃.

Further, the raw materials have the following proportions: 21.5 wt %≤Al₂O₃+B₂O₃+BeF≤26 wt %, 3.5 wt %≤BaF₂+BeF₂+AlF₃≤6.5 wt %, 21 wt %≤P₂O₅+Al₂O₃≤25 wt %, and 5.5 wt %≤BaF₂+BeF₂+AlF₃+La₂O₃+P₂O₅≤7.8 wt %.

SiO₂ is a glass network former, in which sp³ hybrid orbitals of the Si atom form the fundamental structural unit [SiO4] of silicate, and is one of the most important raw materials in the OLED glass. SiO₂ can reduce the thermal expansion coefficient of glass, and improve the chemical stability, mechanical strength, and transmittance of glass. However, when the content of SiO₂ is very high, the melting temperature is high, and crystallization is likely to occur. Based on the performance of the glass of the present invention, the content of SiO₂ is set to 57-62%.

B₂O₃ is a glass network former with [BO3] and [BO4] as structural units, which can improve the chemical and thermal stability of glass and improve the luster of glass, and can further reduce the viscosity of glass as a co-solvent at high temperatures. In addition, it can significantly reduce the surface tension of glass as a surfactant. However, when it is added too much, the performance of glass decreases instead. In this case, in the present invention, the content of B₂O₃ is appropriately 0.5-2%, and 21.5 wt %≤Al₂O₃+B₂O₃+BeF≤26 wt %.

Al₂O₃ is a glass network intermediate with two coordination states in the tetrahedron or octahedron, and there is a tendency to bind to oxygen ions in the presence of B³⁺ and Be²⁺, which interferes with the tetrahedral coordination, so that some Al³⁺ ions may be in the octahedron. Aluminum can form an aluminum-oxygen tetrahedron with double-bonded oxygen in phosphorus-oxygen glass, which can improve the structure of glass, and aluminum oxide can significantly improve the hardness, modulus of elasticity, strain point, and other performance of glass. However, when the content is too high, the melting temperature is very high. In this case, in the present invention, the content of Al₂O₃ is appropriately 20-24%, wherein 21.5 wt %≤Al₂O₃+B₂O₃+BeF≤26 wt % and 21 wt %≤P₂O₅+Al₂O₃≤25 wt %.

BaF, BeF, and AlF₃, as fluorides introduced into glass, have strong glass-forming ability, and can significantly improve the optical performance of glass, improve the stability of glass, expand the light transmission range, effectively reduce the photoelastic coefficient of glass, and increase the Abbe number of glass. In addition, they can promote glass melting and lower the melting temperature of glass. However, excessive introduction may destroy the network structure of glass and affect other performance of glass. In this case, in the present invention, the content of BaF is appropriately 2-5%, the content of BeF is appropriately 0.5-1.5%, and the content of AlF₃ is appropriately 0.2-0.8%, wherein 3.5 wt %≤BaF₂+BeF₂+AlF₃≤6.5 wt % and 5.5 wt %≤BaF₂+BeF₂+AlF₃+La₂O₃+P₂O₅≤7.8 wt %.

La₂O₃, as a rare earth oxide, has a tight atomic orbital structure. La³⁺ is present in the glass network voids, which can effectively improve the optical performance of glass and reduce the chromatic dispersion in glass, and thus has a high Abbe number. In this case, in the present invention, the content of La₂O₃ is appropriately 0.3-0.8%, wherein 5.5 wt %≤BaF₂+BeF₂+AlF₃+La₂O₃+P₂O₅≤7.8 wt %.

P₂O₅ is a glass former oxide that forms the network structure of phosphate glass in the form of [PO4], which can improve the chromatic dispersion coefficient and ultraviolet transmission capability of glass, and reduce the melting temperature of glass. In addition, P₂O₅ has strong surface activity, which can significantly reduce the surface tension of glass. However, when the content is too high, the stability of glass is reduced. In this case, in the present invention, the content of P₂O₅ is determined to be 0.1-0.3%, wherein 21 wt %≤P₂O₅+Al₂O₃≤25 wt %.

A method for manufacturing the OLED glass with improved optical performance includes the following steps:
(1) sieving the silicon dioxide and aluminum oxide with a required mesh number, and stirring uniformly with a stirrer, to prevent defects such as silicon-rich phases, aluminum-rich phases, or unmelted silicon-aluminum substances in a glass product;
(2) mixing all raw materials after weighing and the silicon-aluminum batch uniformly in a mixer to obtain glass raw materials, and transferring the glass raw materials to a feeding port for feeding; and
(3) melting the glass raw materials, thinning molten glass in a tin bath to obtain formed glass, transferring the formed glass through rollers to an annealing furnace for precision annealing, cutting and edge-snapping annealed glass, and detecting various performance of the glass.

The present invention has the following beneficial effects:
1. Different from current ordinary OLED glass, the glass of the present invention has a lower melting temperature and a higher characteristic point temperature, wherein the melting temperature is 1703-1709° C. and the strain point temperature is up to 750° C.; has higher mechanical performance, wherein the Vickers hardness reaches 705 MPa and the modulus of elasticity reaches 86.12 GPa; and has improved optical performance, wherein the transmittance is up to 91.8%, the photoelastic coefficient is 13% lower than the ordinary OLED glass, and the Abbe number increases by 17%.
2. By using the method of sieving the glass raw materials through 80-120 meshes and stirring twice in the present invention, the density of defects of silicon-aluminum knots and unmelted stones in the glass is greatly reduced, and the product yield is increased by 2-3%.
3. The glass of the present invention has improved optical performance while ensuring mechanical performance such as high modulus of elasticity and high Vickers hardness, expanding an application range of the glass, reducing the difficulty in melting, thinning, and formation of the glass, and increasing the product yield.

### DETAILED DESCRIPTION OF THE INVENTION

The following describes the technical solutions in the embodiments of the present invention clearly and completely with reference to examples of the present invention. Apparently, the described examples are merely some rather than all of the embodiments of the present invention. All other examples obtained by a person of ordinary skill in the art based on the examples of the present invention without creative efforts shall fall within the protection scope of the present invention.

### Examples 1-5

Raw materials for an OLED glass with improved optical performance include silicon dioxide, aluminum oxide, boric acid, barium fluoride, strontium carbonate, beryllium fluoride, tin dioxide, lanthanum oxide, phosphorus pentoxide, aluminum fluoride, and silver nitrate, which were weighed in proportions in Table 1 separately for Examples 1-5:

The glasses in Examples 1-5 were all manufactured through the following steps:
(1) First, silicon dioxide and aluminum oxide were sieved through 80-120 meshes, and then stirred uniformly with a stirrer, to prevent defects such as silicon-rich phases, aluminum-rich phases, or unmelted silicon-aluminum substances in a glass product.
(2) All the remaining raw materials were weighed and mixed with the silicon-aluminum batch uniformly in a mixer, and then transferred to a feeding port for feeding.
(3) The glass raw materials were melted, thinned and formed in a tin bath, transferred through rollers to an annealing furnace for precision annealing, and cut and edge-snapped to obtain formed glass, and then various performance of the glass were detected.

### COMPARATIVE EXAMPLE

(1) All the raw materials were weighed in the same proportions as listed in the “Comparative Example” column of Table 1 and mixed uniformly in a mixer, and then transferred to a feeding port for feeding.
(2) The glass raw materials were melted, thinned and formed in a tin bath, transferred through rollers to an annealing furnace for precision annealing, and cut and edge-snapped to obtain formed glass, and then various performance of the glass were detected.

The lithium-aluminosilicate glasses obtained in Examples 1-5 and Comparative Example were tested for performance. Treatment conditions and test results are shown in Table 1:

TABLE 1

| | | Comparative | | | | | |
|---|---|---|---|---|---|---|---|
| | Component | Example | Example 1 | Example 2 | Example 3 | Example 4 | Example 5 |
| Composition | SiO₂ | 59 | 58 | 60 | 61 | 61 | 60 |
| (wt. %) | Al₂O₃ | 22 | 24 | 21 | 21 | 20 | 22 |
| | B₂O₃ | 1.5 | 1 | 0.6 | 2 | 1 | 1.3 |
| | BaF | — | 2 | 5 | 5 | 4 | 5 |
| | SrO | 8.8 | 11 | 11 | 8 | 10 | 10 |
| | BeF₂ | — | 1 | 0.6 | 0.5 | 1.5 | 0.5 |
| | SnO₂ | 0.2 | 0.3 | 0.2 | 0.2 | 0.5 | 0.2 |
| | La₂O₃ | — | 1 | 0.7 | 0.8 | 0.3 | 0.5 |
| | P₂O₅ | — | 1 | 0.3 | 0.5 | 1 | 0.2 |
| | AlF₃ | — | 0.5 | 0.3 | 0.8 | 0.5 | 0.2 |
| | AgNO₃ | — | 0.2 | 0.3 | 0.2 | 0.2 | 0.1 |
| | CaO | 4.5 | — | — | — | — | — |
| | MgO | 4 | — | — | — | — | — |
| Performance | Melting and | 1724 | 1709 | 1705 | 1708 | 1709 | 1703 |
| indicator | clarification | | | | | | |
| | (10 Pa · s) | | | | | | |
| | (° C.) | | | | | | |
| | Start | 1497 | 1470 | 1475 | 1472 | 1478 | 1472 |
| | temperature | | | | | | |
| | for formation | | | | | | |
| | (10² Pa · s) | | | | | | |
| | (° C.) | | | | | | |
| | Operating | 1323 | 1304 | 1308 | 1305 | 1306 | 1305 |
| | point | | | | | | |
| | temperature | | | | | | |
| | (10³ Pa · s) | | | | | | |
| | (° C.) | | | | | | |
| | Softening | 1015 | 1028 | 1030 | 1028 | 1027 | 1025 |
| | point (° C.) | | | | | | |
| | Strain point | 738 | 749 | 750 | 747 | 748 | 748 |
| | (° C.) | | | | | | |
| | Annealing | 791 | 806 | 807 | 805 | 805 | 802 |
| | point (° C.) | | | | | | |
| | Vickers | 698 | 699 | 705 | 702 | 695 | 699 |
| | hardness | | | | | | |
| | (MPa) | | | | | | |
| | (1.961N, 5S) | | | | | | |
| | Thermal | 3.60 | 3.65 | 3.58 | 3.65 | 3.67 | 3.62 |
| | expansion | | | | | | |
| | coefficient | | | | | | |
| | (×10⁻⁶/° C.) | | | | | | |
| | (20-300° C.) | | | | | | |
| | Modulus of | 80.88 | 86.12 | 85.21 | 85.02 | 85.12 | 85.10 |
| | elasticity | | | | | | |
| | (E)/GPa | | | | | | |
| | Shear | 32.80 | 34.54 | 34.29 | 34.24 | 34.17 | 34.52 |
| | modulus | | | | | | |
| | (G)/GPa | | | | | | |
| | Poisson's ratio | 0.23 | 0.25 | 0.24 | 0.24 | 0.25 | 0.25 |
| | (μ) | | | | | | |
| | Photoelastic | 2.60 | 2.25 | 2.23 | 2.28 | 2.25 | 2.26 |
| | coefficient | | | | | | |
| | (10⁻¹²/Pa) | | | | | | |
| | Abbe number | 34.5 | 41.2 | 40.5 | 41.6 | 41.8 | 40.9 |
| | Transmittance | 89.2 | 91.3 | 91.2 | 91.5 | 91.8 | 91.5 |
| | % | | | | | | |
| | (400-800 nm) | | | | | | |
| | Silicon- | 1 | 0 | 0.25 | 0.25 | 0 | 0.25 |
| | aluminum knot | | | | | | |
| | defect density | | | | | | |
| | (knot/m²) | | | | | | |
| | Unmelted | 0.5 | 0.1 | 0.25 | 0.1 | 0.1 | 0.25 |
| | silicon- | | | | | | |
| | aluminum | | | | | | |
| | substance | | | | | | |
| | defect density | | | | | | |
| | (substance/m²) | | | | | | |
| | Product yield | 80% | 83% | 82% | 83% | 83% | 83% |
| | (%) | | | | | | |

The present invention is mainly directed to the OLED glass system. In Table 1, Comparative Example indicates the ordinary OLED glass. In contrast, the glasses in Examples 1-5 have significantly improved mechanical performance, thermal performance, and optical performance. For the glasses in Examples 1-5, the melting and clarification temperatures are significantly lower, and the corresponding characteristic point temperatures are also lower. The temperatures at the softening point, the strain point, and the annealing point are all higher, which fully meets temperature requirements for OLED manufacturing. In addition, the glasses in Examples 1-5 have improved optical performance including higher transmittance, a smaller photoelastic coefficient, and a higher Abbe number, with a high degree of uniformity. By comparing with Comparative Example, in Examples 1-5, the glass raw materials are sieved for particle size uniformity, and the process of mixing is added, thereby greatly reducing the density of defects of silicon-aluminum knots and unmelted stones in the glass. The glass of the present invention has increased optical performance while ensuring mechanical performance such as high modulus of elasticity and high Vickers hardness, expanding an application range of the glass, reducing the difficulty in melting, thinning, and formation of the glass, and increasing the product yield.

In the description of this specification, the terms “an embodiment”, “example”, and “specific example” are intended to indicate that specific features, structures, materials, or characteristics described in conjunction with the embodiment or example are included in at least one embodiment or example of the present invention. In this specification, schematic expressions of the foregoing terms do not necessarily refer to the same embodiment or example. In addition, the specific features, structures, materials, or characteristics described may be combined in any one or more embodiments or examples in a suitable manner.

The foregoing content is merely examples and descriptions of the present invention. Any modifications or additions or substitutions in a similar manner of the described specific embodiments made by a person skilled in the art, as long as they do not deviate from the invention or exceed the scope defined in the claims, shall fall within the protection scope of the present invention.

What is claimed is:

1. An OLED glass with improved optical performance, wherein the OLED glass is made from the following raw materials in percentage by weight: 57-62% of SiO₂, 20-24% of Al₂O₃, 0.5-2% of B₂O₃, 2-5% of BaF₂, 8-11% of SrO, 0.5-1.5% of BeF₂, 0.2-0.5% of SnO₂, 0.3-1.0% of La₂O₃, 0.2-1.0% of P₂O₅, 0.2-0.8% of AlF₃, and 0.1-0.3% of AgNO₃.

2. The OLED glass with improved optical performance as in claim 1, wherein the OLED glass is made from the following raw materials in percentage by weight: 57-62% of SiO₂, 20-24% of Al₂O₃, 0.5-2% of B₂O₃, 2-4% of BaF₂, 8-10% of SrO, 0.6-1.2% of BeF₂, 0.2-0.5% of SnO₂, 0.3-0.8% of La₂O₃, 0.2-0.8% of P₂O₅, 0.2-0.7% of AlF₃, and 0.1-0.25% of AgNO₃.

3. The OLED glass with improved optical performance as in claim 1, wherein the OLED glass is made from the following raw materials in percentage by weight: 57-62% of SiO₂, 20-24% of Al₂O₃, 0.5-2% of B₂O₃, 2-4% of BaF₂, 8-10% of SrO, 0.6-1.2% of BeF₂, 0.2-0.5% of SnO₂, 0.3-0.8% of La₂O₃, 0.2-0.6% of P₂O₅, 0.3-0.7% of AlF₃, and 0.1-0.25% of AgNO₃.

4. The OLED glass with improved optical performance as in claim 1, wherein the raw materials have the following proportions: 21.5 wt %≤Al₂O₃+B₂O₃+BeF≤26 wt %, 3.5 wt %≤BaF₂+BeF₂+AlF₃≤6.5 wt %, 21 wt %≤P₂O₅+Al₂O₃≤25 wt %, and 5.5 wt %≤BaF₂+BeF₂+AlF₃+La₂O₃+P₂O₅≤7.8 wt %.

5. A method for manufacturing the OLED glass with improved optical performance as in claim 1, comprising the following steps:
(1) sieving the SiO₂ and the Al₂O₃ with a required mesh number, and stirring uniformly with a stirrer, to obtain a silicon-aluminum batch;
(2) mixing all the remaining raw materials after weighing and the silicon-aluminum batch uniformly in a mixer to obtain glass raw materials, and transferring the glass raw materials to a feeding port for feeding; and
(3) melting the glass raw materials, thinning molten glass in a tin bath to obtain formed glass, transferring the formed glass through rollers to an annealing furnace for precision annealing, and cutting and edge-snapping annealed glass, to obtain the OLED glass.
